(19) United States
(12) Patent Application Publication
(10) Pub. No.: US 2010/0301337 A1
(43) Pub. Date: Dec. 2, 2010

(54) ELECTRONIC DEVICE WITH SELF-ALIGNED ELECTRODES FABRICATED USING ADDITIVE LIQUID DEPOSITION

(76) Inventors: Christopher B. Rider, Cambridgeshire (GB); Andrew Clarke, Cambridgeshire (GB)

Correspondence Address: EASTMAN KODAK COMPANY;PATENT LEGAL STAFF, 343 STATE STREET, ROCHESTER, NY, 14650-2201, US

(21) Appl. No.: 12/675,205

(22) PCT Filed: Aug. 14, 2008
(86) PCT No.: PCT/GB2008/002747

§ 371 Date: Feb. 25, 2010

(30) Foreign Application Priority Data
Sep. 1, 2007 (GB) 0717055.8

(51) Int. Cl. H01L 29/786; H01L 29/423; H01L 29/417

(52) U.S. Cl. 257/57; 257/618; 257/E29.116; 257/E29.123; 257/43; 257/66; 257/E29.273

(57) ABSTRACT

The invention provides a multilayer electronic device having electrodes, formed on a laterally extending first layer, the lateral position of each of at least two adjacent electrodes being defined by a channel in the first layer. Each channel is adjacent a deposition region, the material which forms each electrode substantially covering the deposition region to form a continuous conductive structure.

### FIELD OF THE INVENTION

The invention relates to electronic devices, in particular to a thin film transistor.

### BACKGROUND OF THE INVENTION

The development of silicon-based thin-film transistor (TFT) technology has been an essential enabler for the development of large flat panel displays. Despite the huge cost of factories to manufacture TFTs on glass and the complexity of the TFT manufacturing process, the technology is now well-established for active matrix LCDs and is based largely on photolithographic techniques for depositing patterns of the various materials into multilayer structures.

In recent years great progress has been made on TFT technologies based on other semiconductors including polymers, metal oxides and semiconducting nanowires and nanotubes. Many of these approaches benefit from simpler processes that promise greatly reduced commercialisation investment compared to the current silicon-based factories. Another recent development has seen liquid processed semiconductors deposited onto flexible substrates using additive approaches such as inkjet and conventional printing and this promises further process simplification and cost-reduction as more processes can be performed in roll-to-roll configurations.

These new approaches to the production of TFTs can also be applied to the production of other optoelectronic devices such as photovoltaics, photodetector arrays for scanning applications or image capture and organic light emitting diode arrays for electronic displays or sensors.

A common need for all thin film optoelectronic devices, especially arrayed structures such as displays or scanners, is the provision of conductive bus lines and electrodes. In a display, for example, data bus lines connect pixel electrodes together in rows and columns. Other bus lines provide power to the pixels. It is important that the bus lines should be highly conductive so that resistive losses are minimised and device non-uniformities are avoided. Usually, the requirements for the conductivity of the pixel TFT electrodes are not so severe as for the bus lines, but the need for high resolution electrode patterning is more important. It is preferred that TFT gate electrodes should not overlap substantially with the source and drain electrodes to minimise parasitic capacitance. Gate electrode widths below 10 microns are not uncommon and with the drive to increase switching speeds and reduce TFT footprint within the pixel area, there is a need to further reduce all the dimensions of the TFT.

When fabricating a multi-layer TFT device, accurate registration between the features in all the layers is very important if optimum device performance is to be achieved. Certain features, however, require greater alignment accuracy than others. Alignment of the gate electrode with the channel region of a TFT formed between the source and drain electrodes is very important and overlap between the gap and source and drain electrodes is to be avoided. On the other hand, the semiconductor and dielectric layers may significantly overlap the device electrodes without detriment to performance, provided that adequate isolation is achieved between neighbouring TFTs and between neighbouring pixels so that leakage currents do not cause inter-pixel cross-talk. Thus, some features of a TFT require accurate and high-resolution pattern registration, while others do not.

During a TFT manufacturing process many separate steps are typically required. Between each step and even during a step, environmental conditions such as ambient temperature and humidity may change, causing changes in dimensions of the carrier substrate for the TFTs and of masks or positioning equipment for deposition or patterning tools. Thus registration errors may accumulate between TFT layers. The temperature of the substrate and deposition or patterning tools may also change during an individual process step as sources of heat are frequently necessary for deposition, patterning or post deposition treatments. These temperature changes also cause dimensional changes within a single patterned layer and again registration may be affected. There is therefore a need to accurately control registration and alignment as well as the dimensions of individual patterns throughout the manufacturing process of thin film optoelectronic devices in general.

Another important issue to be considered is the efficient use of materials. In the well-known photolithographic process used for semiconductor device manufacture, materials are deposited over the whole device substrate and removed pattern-wise. This subtractive approach, while highly reliable and accurate, is wasteful of materials. It is preferable where possible to use additive processes in which materials are only deposited where they are required. In recent years, ink-jet deposition has been widely used to place small droplets of material onto surfaces. This technique enables significant reduction in material wastage because it is an additive process.

For large feature sizes, additive processes offer great promise as patterned deposition technologies. For small feature sizes, however, additive processes, such as conventional printing and inkjet have more limited applicability. Inkjet droplet sizes are typically of the order of a few picolitres. A 1 pl droplet has an in-flight diameter of 12 microns. When it lands it spreads and depending on the surface energy of the substrate and the surface tension of the liquid, the diameter of the circle that is now covered with liquid could be much larger than the diameter of the original droplet. This significantly limits the resolution of patterning that can be achieved. Furthermore, there is a limit to the accuracy with which inkjet droplets can be placed at a precise location on a surface.

Many approaches have been suggested to reduce the pattern resolution limitations arising from inkjet droplet sizes. US 2005/0170550 describes the use of banks of appropriate wettability formed on a surface to contain liquid droplets that are incident on the surface between a pair of banks. The process for forming the banks and for profiling the wettability of the sides requires several steps. U.S. Pat. No. 7,115,507 describes a method of restricting the lateral spreading of a liquid droplet on a surface by the use of indent regions.

When making electronic devices such as TFTs using largely solution-based deposition processes, there have been many approaches to overcome the problem of aligning the gate electrode with the semiconductor channel region. WO 03/034130 describes a method of using the topology of a liquid film while it is still wet to align a second liquid, immiscible with the first, deposited on top of it. US 2005/0071969 describes a method of embossing a groove and building an electronic device in the groove. WO 2004/055920 describes a method for making electronic devices in which a surface topology is defined in a lower layer, preferably by embossing, and a non-planarising upper layer is deposited such that liquid applied to the upper layer conforms to the topology defined originally in the lower layer. Various methods of constructing TFTs are proposed but these require many extra process steps to manipulate the wettability of surfaces and to achieve alignment of the gate and the TFT semiconductor channel. A further difficulty is the use of raised topologies in some embodiments which suffer greatly reduced capillary flow speeds due to the convex profile of the surface of the liquid as it flows along the channel.

Managing the flow of liquid on the surface of the substrate on which the electronic devices are fabricated is a key issue, especially given the need to reduce processing time to a minimum so that fabrication costs are low. Care must be taken to avoid droplets of functional material both bridging between two wettable features closely spaced on a surface and creating voids within a feature that become defects. US 2006/0091547 describes a method for providing a linear region and a wider region both enclosed by banks, such that the thickness of the dried film formed after jetting droplets into the region between the banks is substantially uniform. US 2005/0005799 describes a method for jetting a series of spaced droplets into a long narrow lyophilic channel so that the droplets do not wet the top surfaces of the channel but flow off them into the channel. The spacing between neighbouring droplets is such that they fill the channel and merge with one another to form a continuous stripe of liquid. No liquid remains on top of the channel walls, even if the original incidence of the droplet was partly on the top as well as the walls of the channel. In this method, adjacent channels must have a lyophobic surface between them that is wider than the droplet width on impact to ensure that any droplet never bridges the gap between two adjacent channels. This limits the closest approach between neighbouring channels. Furthermore, it is generally much harder to get good adhesion between a lyophobic surface and a layer that is deposited on top of it. This can lead to mechanical weakness in multilayer devices of the kind addressed by the present invention.

### PROBLEM TO BE SOLVED BY THE INVENTION

Each of the prior art documents address several but not all of the problems simultaneously. It is the object of the present invention to provide an electronic device, in particular a thin film transistor, fabricated rapidly by additive liquid deposition techniques offering the patterning of very fine features and gaps between features, including self alignment of electrodes in multilayer structures where the electrodes are not all in the same layer, and substantially avoiding defects due to open-circuits, short-circuits and mechanical failure between layers.

### SUMMARY OF THE INVENTION

According to the present invention there is provided a multilayer electronic device having electrodes, formed on a laterally extending first layer, the lateral position of each of at least two adjacent electrodes being defined by a channel in the first layer and wherein each channel is adjacent a deposition region, the material which forms each electrode substantially covering the deposition region to form a continuous conductive structure.

### ADVANTAGEOUS EFFECT OF THE INVENTION

The electronic device of the invention is fabricated using a method that is self-aligning and is therefore insensitive to substrate distortion during manufacture and very accurately aligns, for example, the gate of a thin film transistor (TFT) to the source and drain with no overlap of the gate electrode with the source and drain electrodes, thus minimising parasitic capacitance. This further improves reproducibility between devices fabricated on the same substrate at different times, thus improving performance and reducing defects.

The invention allows the semiconductor channel length to be reduced to substantially below printing resolutions. It enables gaps between device features to be brought much closer with respect to the deposited width of an inkjet droplet. Bringing the electrodes closer together reduces, in the case of a TFT, semiconductor channel length thus increasing switching speeds and reducing the device footprint. Electrodes with widths down to 100 nm can routinely be achieved in devices of the present invention and it is possible to achieve feature sizes of tens of nm by judicious choice of material and great care in the manufacturing process.

The device of the invention can be manufactured using a rapid additive deposition process that reduces material waste and enables cost reduction by reducing manufacturing waste and time.

The invention provides better adhesion of overlayers to the substrate since it does not have to have a lyophobic characteristic on the areas where the flowable material should not flow. The closest approach of two channels can be much closer because there is no need to have a large lyophobic land between the channels.

The invention also allows the pre-patterning step to be simplified and thus further reduces the cost and time to manufacture electronic devices. There is no requirement for, for example, the formation of banks or areas of surface energy contrast. In a preferred embodiment embossing alone is enough to prepare the substrate for patterning. Embossing is a low cost technique and may be done roll-to-roll so that incremental costs in preparing the substrate for deposition are minimised versus some of the other routes. Embossing is also possible down to features sizes of 100 nm and thus enables very high resolution features to be made. Therefore this approach enables high resolution patterns to be made.

Devices in accordance with the invention are more uniform because they are less sensitive to deposition coverage variation, being relatively insensitive to variants of the flowable materials deposited in the deposition region.

### BRIEF DESCRIPTION OF THE DRAWINGS

The invention will now be described by way of example with reference to the following drawings in which:

FIG. 1 illustrates a prior art device;

FIGS. 2a to 2d illustrate channels and deposition regions and the topology of a substrate prior to making a device in accordance with the present invention;

FIGS. 3a to 3j illustrate various channel geometries that may be used;

FIGS. 4a to 4g illustrate how a TFT in accordance with the invention may be made;

FIG. 5 illustrates the channel angle and the condition for capillary flow in a channel; and

FIG. 6 illustrates the fabrication of a bus line incorporated into a deposition region.

### DETAILED DESCRIPTION OF THE INVENTION

The present invention will now be described using the example of a TFT. It will be understood by those skilled in the art that all kinds of multilayer electronic devices having more than one electrode will benefit from the present invention. See “Physics of semiconductor devices” by Sze and Ng, third edition, published by Wiley for a full description of many types of semiconductor devices and their architectures.

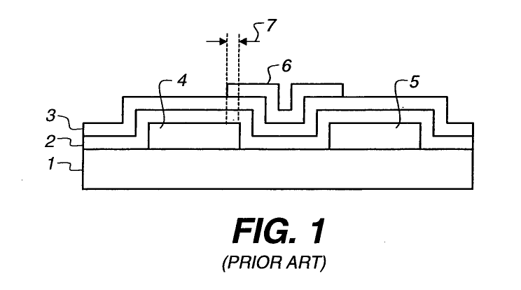

FIG. 1 shows a prior art top-gate TFT as an example although it will be recognised that the same disadvantages occur with bottom-gate architectures and with other design variants of the basic TFT concept illustrated. Source electrode 5 and drain electrode 4 are formed on a substrate 1 by any convenient means. The dominant patterning technology in high performance semiconductor devices has been photolithography, used to pattern largely vacuum deposited materials. A thin semiconductor layer 2 is formed by any convenient means over the substrate and electrodes and a thin dielectric layer 3 is further formed thereon. Both semiconductor and dielectric layers are illustrated as non-planarising or conformal, by which is meant that the approximate surface topology of source and drain electrodes on the substrate remain after deposition of the semiconductor and gate dielectric layers. A gate electrode 6 is deposited by any convenient means. If the gate electrode is deposited by a vacuum coating process, for example, thermal evaporation, it will be necessary to use a shadow mask. The mask must be aligned to the pattern of the source and drain electrodes before the deposition begins. Usually there is an alignment tolerance of the mask with the underlying pattern and there is a vertical overlap 7 between the source electrode and the drain electrode. It is this overlap that causes unwanted parasitic capacitance in the device. The overlap may vary from one side of the device to the other depending on the alignment of the shadow mask. The overlap may also vary from device to device across the area of the substrate. Furthermore the alignment of the shadow mask may vary during the deposition as the mask and its frame heat up and expand. In extreme cases, the gate may be so misaligned with the source and drain that the device does not work properly.

The present invention provides a multilayer electronic device which is insensitive to such alignment issues by using channel features in the substrate to direct flowable materials deposited in a deposition region to form the electrodes of the device. As the channel features in the substrate remain in relative alignment during fabrication, even if the substrate distorts slightly, only coarse positioning is required during deposition of the electrode material, provided substrate topology remains after deposition of non-planarising intermediate layers so that electrode materials in the upper layers of the device may be directed to the correct location by capillary forces. It is a key feature of devices of the present invention that the electrodes are fabricated using materials that are flowable rather than for example vacuum deposited by evaporation or sputtering.

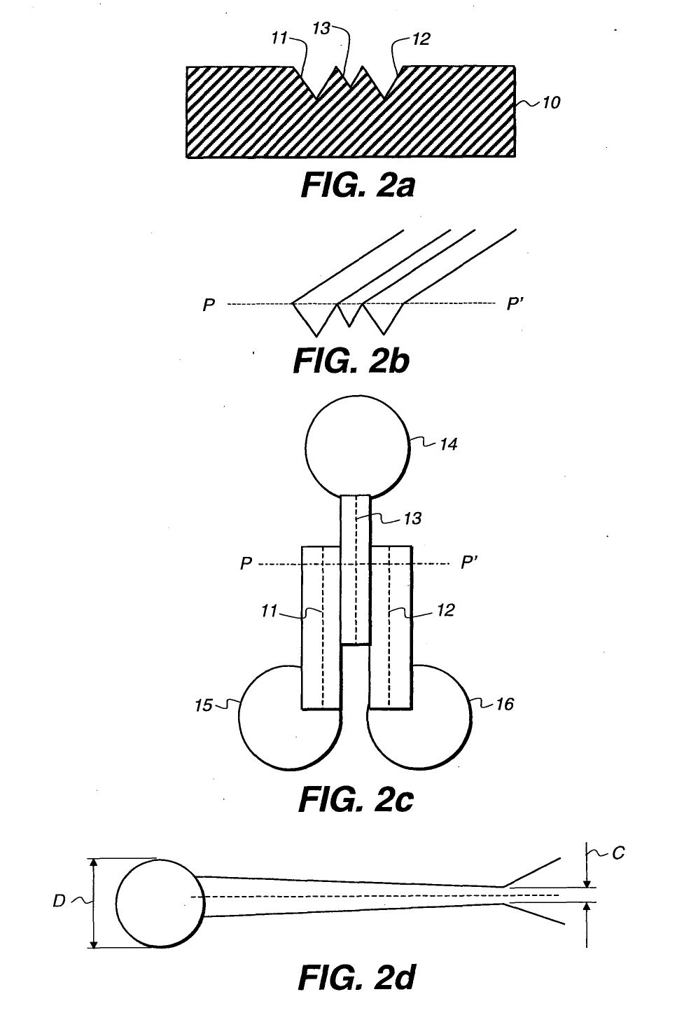

FIG. 2a shows a cross-sectional view of the substrate 10 of the device in accordance with the invention along the line PP′ as shown in FIGS. 2b and 2c. Three channels have been formed in the substrate by any convenient means, for example, stamping, embossing, moulding, cutting, laser ablation, etching or milling. Preferred methods are stamping and embossing. The example of FIG. 2a of the present invention is a TFT, which has three electrodes. The substrate may comprise a rigid material or a rigid material that is overcoated with a soft material that is suitable for formation of the channels. The substrate may alternatively be entirely composed of a soft material, for example a polymer such as polyethylene terephthalate, polyethersulphone, polymethylmethacrylate, polypropylene or polyethylnaphthalate. Where polymeric materials are used for the substrate, the channels may conveniently be formed by embossing during the manufacture of the substrate by raising the polymer towards its glass transition temperature and applying an embossing master under pressure. This is a very low cost method of forming channels which is applicable to high speed manufacture of large areas of polymeric web in a roll to roll process. FIG. 2b is an isometric view of the three channels and the cross-section at the line PP′. FIG. 2c is a plan view of the structures formed in the substrate. Each of the three channels has associated with it a deposition region, 14, 15 and 16, into which flowable material may be deposited. The deposition region may be constrained by boundaries, such as banks, surface energy contrast, or a recessed region or it may be entirely or partially undefined on the surface of the substrate. Furthermore, deposition regions may overlap so that when material is deposited in such overlapping deposition regions a continuous pattern is formed.

Each deposition region has an associated channel, such that when flowable material is deposited into a deposition region it spreads until the wetting line comes into contact with the channel, at which point the flowable material is directed into the channels by capillary forces. Flowable material is supplied to a deposition region by any convenient method such as by conventional printing e.g. lithographic printing, flexographic printing, screen printing, pad printing, gravure printing, intaglio printing and also by digital printing techniques such as ink-jet printing and electrophotographic printing. These are examples only. The liquid will continue to flow into the channel from the deposition region, until either it reaches the end of the channel or until the volume of liquid in the deposition region is reduced to the point that the pressures of the liquid in the deposition region and the channel region are equal.

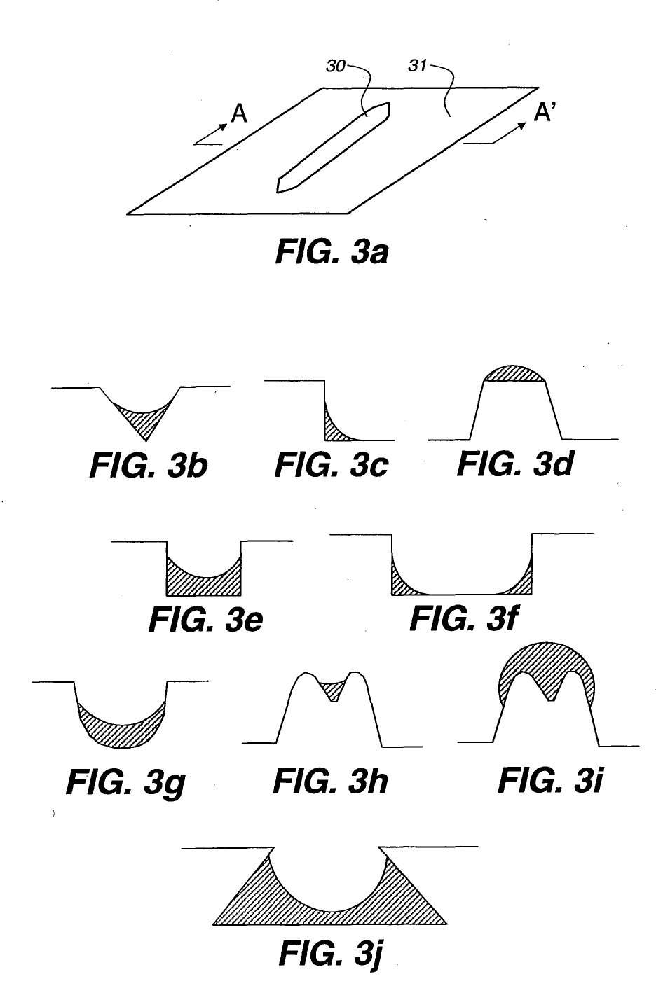

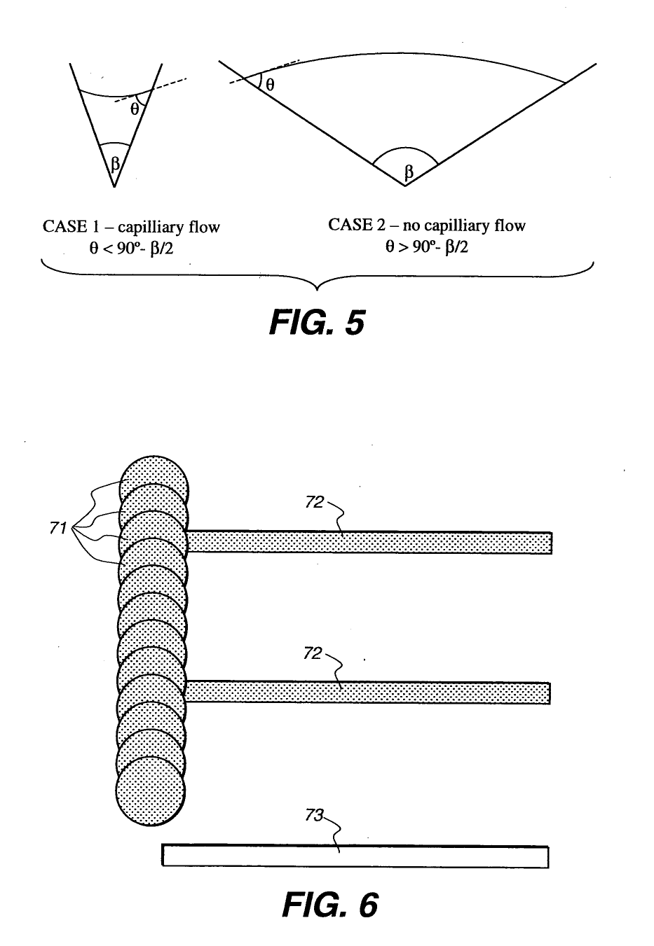

“Channel” 30, as illustrated in FIG. 3a includes any linearly extended topology on a substrate surface 31 that confines liquid by means of capillary force. It includes, but is not limited to, recessed areas, raised “lands” bounded by sharp-edged descending walls and steps where the flowable material is confined to and directed along the base of the step. Channel topology may be characterised either as convex or concave by which is meant that a channel can be said to be concave if the liquid is confined within the channel structure. A convex channel is one in which the liquid is confined outside the channel structure. A flat surface, which is by definition neither convex nor concave, cannot confine liquid by surface topology and liquid placed on a flat surface spreads freely until the contact angle at the wetting line is less than the advancing contact angle. FIG. 5 defines the channel angle β for a V groove channel. Note that the channel angle is defined by the intercept of the projection of the side walls at the wetting lines, rather than the actual shape of the base of the channel, although in the case of FIG. 5 the two are the same.

FIG. 3b illustrates a V groove channel with a channel angle of just less than 90° showing liquid confined within the channel. This channel geometry is concave. FIG. 3c illustrates a channel with a channel angle of 90° configured as a step. Liquid is confined at the base of the step. Capillary forces are much stronger than gravitational forces over distances less than the capillary length (typically a few millimetres) and so the orientation of the channel in space is irrelevant. Liquid would be confined in the V groove of FIG. 3b or the step of FIG. 3c whether or not the substrate was orientated upwards or downwards. Therefore the structures illustrated in FIGS. 3b and 3c are almost identical in terms of their confinement efficiency. A difference would arise if the channel in FIG. 3b were filled to the top, at which point the liquid would pin on the topological discontinuities on either side of the channel. In the case of FIG. 3c, there is a discontinuity to the left hand side of the channel that would act as a pinning point, but such a discontinuity is not shown on the right hand side and so liquid would not be confined and would be free to flow until the advancing contact angle is reached.

FIG. 3d is an example of a convex channel with a channel angle of 180°. Liquid is contained on the outside of the channel structure. In fact, the flat land on the top of the protrusion does not contain the liquid in the same way as the channels of FIGS. 3b and 3c where capillary interactions with the walls and the nature of the wall geometry contain the liquid. In FIG. 3d, it is only the discontinuities at either side of the flat land that pin the wetting line and confine the liquid. If a small droplet of liquid were placed on the flat land and allowed to spread, it would do so freely as on a flat surface, without the enhancement of capillary flow that comes from interaction between the wetting line at its leading edge and the surface profile at the base of a V groove channel.

FIG. 3e shows a rectangular channel, also an example of a concave channel, with a channel angle of 0° since the planes of the channel walls where the wetting lines on either side of the channel are situated do not intersect. FIG. 3f illustrates another much wider rectangular channel in which the volume of liquid contained is not enough to wet the whole of the bottom of the channel. The channel therefore behaves as two step channels as shown in FIG. 3c that do not communicate with each other. FIG. 3f is therefore illustrating two concave channels with channel angles of 90°. It is noted that within a rectangular channel such as 3e and 3f, it is possible to have liquid at the leading edge of the capillary flow filling the channel as illustrated in FIG. 3f whereas further back from the leading edge, where the channel has a higher volume of liquid contained within it, it may fill the channel as illustrated in FIG. 3e.

It is not necessary to have sharp geometries to confine liquid as shown in FIGS. 3g and 3h, which are both examples of concave geometries with channel angles of approximately 10° and 60° respectively. The channel of FIG. 3i, however, despite having the same topology as the channel of FIG. 3h has a greater volume of liquid being confined such that the inner channel shape cannot contain all the liquid. The channel angle is now approximately 325°. Liquid is still confined, but the confinement of the wetting line is now on the outside of the structure and this is therefore an example of a convex channel. It will be recognised that the geometry of FIG. 3i is highly unstable and there is a significant risk that the liquid will run down the walls of the channel at the slightest perturbation. FIGS. 3h and 3i illustrate that it is sometimes not possible to define a channel as concave or convex simply by its topology as the position of the wetting lines are needed to understand the nature of the confinement. For the sake of clarity, in FIG. 3i, had only one side of the inner channel overflowed so that only one of the wetting lines had been situated on the outside of the structure, it would still be functionally a convex channel. It is necessary for both the wetting lines to be on the inside of the structure for it to be defined as concave.

FIG. 3j is another example of a concave structure but with a channel angle of −90°. Channels with a negative channel angle are narrower at their upper opening than at their base. Although this structure is very effective at wicking liquid and confining it, owing to difficulties in manufacture of such structures by low cost processes, it is not a preferred embodiment.

Channels of the present invention are concave by which is meant that they have a channel angle greater than −180° and less than 180°. More preferably channel angles of the present invention are greater than −150° and less than 150° such that capillary enhancement to the flow of the functional material in the channel is more significant. Most preferably channel angles are greater than 0° (for ease of manufacture of the channel by stamping or embossing) and less than 90° to further enhance capillary wicking and widen the range of functional materials which can be used. It is not necessary for the channels to have sharp-edged pinning points defining the boundaries of the channel and preventing overflow, but channels with preferred topologies have at least one sharp-edge pinning point and preferably two.

Flowable material is deposited in the deposition region, which is of larger maximum extent than the channel width to facilitate correct location of the flowable material, given that positioning tolerances of the deposition technique and the lateral extent of the minimum volume of liquid that may be deposited may be much larger than the dimensions of the channel. In a preferred embodiment the channel width is less than the resolution of the deposition method. All printing methods routinely achieve minimum feature widths of 100 microns, but below this value accurate definition of features becomes increasingly difficult. Screen printing for example, struggles to achieve gaps between features below 50 microns. Typical inkjet resolutions are limited by the width of the droplet after impact with the surface and typically achieve a minimum feature size of 40 microns. Offset lithography and gravure printing can achieve feature sizes of 30 microns when extremely well controlled. No conventional printing technique can routinely achieve feature sizes and gaps between features of 10 microns, which would be at the upper end of the preferred dimension range for construction of TFT features.

It will be recognised, as illustrated in FIG. 2d, showing a plan view of a channel and deposition region, that the width of the deposition region, being defined as the maximum extent of the deposition region, D, as measured in any direction in the plane of the substrate will be significantly larger than the width of the channel, C, where width of the channel is measured across the channel at its widest transverse dimension—i.e. the width at the “top” of the channel (in the case of a concave channel)—measured in a direction perpendicular to its length in the plane of the substrate at the narrowest point in the channel. Therefore, should the channel width vary along its length, the channel width should be measured at its narrowest point, C, as illustrated in FIG. 2d.

The flowable material includes any material which can be used in the fabrication of electrodes, either directly or as part of another process step, for example electroless plating onto a catalyst-containing material and may include conductive inks, seed inks, metal nanoparticulate containing inks, conductive polymers, metal soaps, liquid metal alloys and other precursor materials. Flowable material also includes materials that are deposited in the deposition region in solid or highly viscous form, but which on heating become flowable and are able to move rapidly under the action of capillary forces. Solders and phase-change inks are examples of materials that become flowable when heated.

When considering wetting behaviour of surfaces, conventionally an advancing contact angle is defined. If a sessile drop is formed and liquid added slowly, then the advancing angle is defined as the angle between the tangent of the liquid surface and the substrate measured at the three-phase line and through the liquid as the line just begins to advance. For more information on this topic see for example “Capillarity and Wetting Phenomena” by Gilles De-Gennes, Brochard-Wyart and Quere published by Springer 2003. Likewise, the receding contact angle can also be defined. If a sessile drop is formed and liquid removed slowly from the drop, then the receding contact angle is defined as the angle between the tangent of the liquid surface and the substrate measured at the three-phase line and through the liquid as the line just begins to recede. Wetting hysteresis is defined as the difference between the advancing and receding angles. A surface is termed reversible if it has zero wetting hysteresis. The rate of wicking along the channel may be controlled by the channel angle, β, defined in FIG. 5. The greater the channel angle, the slower the rate of wicking will be. When the advancing contact angle, θₐ, is less than (90°−β/2) wicking will occur as described in “Flow of simple liquids down narrow V grooves”, Mann et al., Phys. Rev. E, 52, p 3967, 2005. Preferably, θₐ should be set somewhat below this figure to facilitate rapid wicking along the channel and thus minimise evaporation losses from the liquid which may change its flow characteristics as it wicks.

It has been found that evaporation losses can significantly affect the distance over which liquid will wick along a channel. It is therefore preferable to use small channel angles less than 150° and mostly preferably less than 90°.

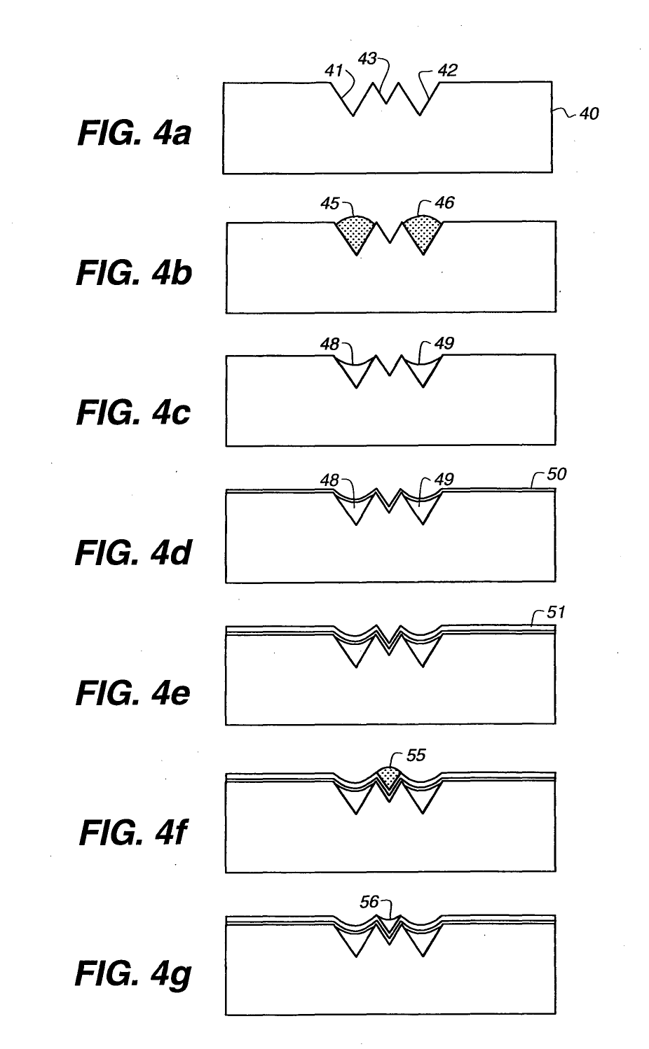

FIG. 4 illustrates a method by which a TFT in accordance with the present invention may be manufactured, by way of example. A substrate is provided with three channels for source, 41, drain, 42 and gate, 43, electrodes and three associated deposition regions (not shown in FIG. 4a). A conductive ink is deposited into the deposition regions associated with the source and drain channels by any convenient method, for example, by ink-jet printing. The ink will spread in the deposition regions until the wetting line reaches the channel where it will wick down the channel by capillary forces. When the ink reaches equilibrium, such that pressures at the surface of the liquid in the deposition region and the channel are equal everywhere, the liquid will have stopped flowing and the profile of the surface of the liquid may appear as shown in FIG. 4b. The exact surface profile of the liquid at equilibrium will depend on the static contact angle of the ink with the walls and the volume of liquid in the channel and deposition region. If the volume of ink deposited in the deposition region is significantly greater than the volume of the channel it is possible for the channel to overflow. If however, the volume of ink deposited is just slightly greater, the channels will not overflow and the rest of the volume of ink will remain in the deposition region, provided it does not dewet. The issue of dewetting of the flowable material in the deposition region is to be avoided.

In this particular example, the ink used is a conductive metal nanoparticulate ink, supplied by one of several companies, for example, Cabot silver aqueous conductor AG-IJ-G-100-A1-X. It has been found that aqueous dispersions of silver nanoparticles are preferred but gold nanoparticle inks may also be used. After deposition, the nanoparticles must be sintered by heat both to drive off solvent and to fuse the metal particles to form a highly conductive continuous structure. During this process there is some shrinkage and after sintering, the material will change its surface contour as shown in FIG. 4c. The next step in the process is to deposit the semiconductor layer 50 as shown in FIG. 4d. Any non-planarising coating of semiconductor can be used, for example, amorphous silicon, zinc oxide, low temperature polysilicon. A preferred semiconductor is zinc oxide, which can be conveniently deposited by atomic layer deposition or sputtering. See the paper, “A comprehensive Review of ZnO materials and devices”, by Ozgur et al, Journal of Applied Physics 98, 041301 (2005), for recipes for the atomic layer deposition or sputtering of suitable ZnO films for TFT fabrication. The gate dielectric 51 is then deposited by another non-planarising process. One of the many metal oxides may be chosen for this purpose, for example, silicon dioxide, aluminium oxide, titanium dioxide and hafnium oxide. However, with zinc oxide as the semiconductor, it is found that aluminium oxide is a preferred material. This may be deposited, for example, by atomic layer deposition or sputtering. It will be noted in FIG. 4e that the topology defined in the substrate at the gate channel is still evident in the topology of the dielectric layer. The same is also true for the deposition region corresponding to the gate channel (not shown in FIG. 4e). To form the gate electrode, a conductive ink is deposited into the gate channel deposition region and the ink 55 wicks by capillary forces along the topological feature on the dielectric layer corresponding to the gate channel. After sintering, the gate electrode 56 is formed in perfect alignment with the source and drain electrodes 48 and 49 and the semiconductor channel region that lies between them. The construction of the TFT is then complete.

It will be appreciated that the width of the gate electrode is either less than or just equal to the topological feature defined in the layer into which the electrode is formed. This topological feature will closely correspond to the dimensions and topology of the channel formed in the substrate especially if the non-planarising layers are thin with respect to the channel dimensions. The exact width of the electrode will be determined at least in part according to how full of conductive ink the channel was filled and how much shrinkage there was in forming the highly conductive material that forms the electrode.

It will now be appreciated that the use of adjacent V-groove concave channels in the substrate enables the fabrication of electronic devices with multiple electrodes wherein the electrodes can approach each other very closely without short circuits. By “adjacent”, is meant channels which when viewed in plan, are closest to each other when measured in a direction perpendicular to their length and in the same plane parallel to the substrate. It is also possible if so desired to separate adjacent V-groove channels with a small land to maximise isolation between electrodes. A particular benefit of devices in accordance with the present invention is that the gap between electrodes may be much less than is possible relying only on the resolution of the deposition technique. Preferred separation of electrodes is less than 50 microns, more preferably less than 20 microns and most preferably less than 5 microns. This advantage of close approach of the electrodes is also enabled by the technique of wicking conductive liquids along the channels from a remote deposition region rather than endeavouring to deposit the conductive liquids into the location where the electrodes are desired to be formed as this greatly reduces the possibility of overfilling the channels. The technique of wicking liquid from the deposition region effectively “meters” the liquid into the channel, which is then pulled along the channel by capillary forces. This avoids the need to “force” liquid into the electrode region under pressure, which would greatly increase the probability of short circuits between the closely spaced electrodes which are a benefit of the present invention. Furthermore, there is no need to perform complex differential surface treatments to contain the liquid by differential surface energy patterning. This greatly reduces the number of process steps needed to manufacture the devices and therefore reduces manufacturing time and cost.

A further benefit of the devices according to the present invention is that there is no overlap between adjacent channels, which serves to reduce unwanted parasitic capacitances between electrodes.

TFTs are frequently manufactured in arrays, for example to drive displays or in sensor arrays and it is often necessary to connect the electrodes of a TFT to an array of others. FIG. 6 illustrates a bus line formed of multiple overlapping drops of conductive ink 71. As the bus line is written, the liquid wets the channels 72 and ink is drawn from the still wet bus line into the channels which might lead to individual devices. Channel 73 is still empty as the wetting line of the leading edge of the bus line has not reached it yet. In this way, the deposition region of a channel may often form part of another structure and it is therefore essential to ensure a continuous conductive connection between the material in the deposition region and the electrode.

The TFT has been described being manufactured by top gate architecture. Exactly the same surface pattern can be used for bottom gate architecture.

The invention has been described in detail with reference to preferred embodiments thereof. It will be understood by those skilled in the art that variations and modifications can be effected within the scope of the invention.

1. A multilayer electronic device having electrodes, formed on a laterally extending first layer, the lateral position of each of at least two adjacent electrodes being defined by a channel in the first layer and wherein each channel is adjacent a deposition region, the material which forms each electrode substantially covering the deposition region to form a continuous conductive structure.

2. A device as claimed in claim 1 wherein each channel is concave.

3. A device as claimed in claim 1 wherein the lateral position of each deposition region is defined by a topological feature in the first layer, the width of the associated channel being less than the width of the topological feature.

4. A device as claimed in claim 1 wherein the width of each of the at least two electrodes is less than or equal to the width of the channel that defines its lateral position.

5. A device as claimed in claim 1 wherein the at least two electrodes are located on opposite sides of at least one non-planarising intermediate layer.

6. A device as claimed in claim 5 wherein the non planarising intermediate layer is continuous across the device.

7. A device as claimed in claim 1 wherein there is no overlap between the at least two electrodes when viewed in a direction perpendicular to the plane of either electrode.

8. A device as claimed in claim 1 wherein the gap between the at least two electrodes at their closest point of approach is less than 50 microns in the plane of either electrode.

9.-10. (canceled)

11. A thin film transistor having a source electrode, drain electrode and gate electrode formed on a laterally extending first layer, wherein the lateral position of the gate electrode is defined by a channel in the first layer.

12. (canceled)

13. A transistor as claimed in claim 11 wherein the width of the gate electrode is less than the width of the channel that defines its lateral position.

14. A transistor as claimed in claim 11 wherein the lateral position of at least one of the source electrode or drain electrode is defined by a channel in the first layer.

15. A transistor as claimed in claim 11 wherein the gate electrode and the at least one of the source electrode or drain electrode are adjacent a deposition region, the material which forms each electrode substantially covering the deposition regions to form continuous conductive structures.

16. A transistor as claimed in claim 11 wherein the gate electrode and at least one of the source electrode or drain electrode are on opposite faces of at least one non planarising intermediate layer.

17. (canceled)

18. A transistor as claimed in claim 11 wherein the gate electrode and at least one of the source electrode and drain electrode do not overlap laterally when viewed in a direction perpendicular to the plane of either electrode.

19. A transistor as claimed in claim 11 wherein the gap between the gate electrode and at least one of the source electrode and drain electrode at their closest point of approach is less than 50 microns in the plane of either electrode.

20. (canceled)

21. A transistor as claimed in claim 19 wherein the gap is less than 5 microns.

22. A transistor as claimed in claim 11 wherein at least one electrode is adjacent a deposition region.

23. A transistor as claimed in claim 22 wherein the material forming the electrode also substantially covers the deposition region to form a continuous conductive structure.

24. A device as claimed in claim 1 wherein the laterally extending first layer is either a polymer web or a metal foil coated with an insulating layer, the channels being formed by stamping, embossing or by a laser process.

25. A device as claimed in claim 1 wherein the channels have a V shaped cross section.
